(19) United States
(12) Patent Application Publication
(10) Pub. No.: US 2017/0263525 A1
(43) Pub. Date: Sep. 14, 2017

(54) ELEMENT CHIP AND METHOD FOR MANUFACTURING THE SAME

(71) Applicant: Panasonic Intellectual Property Management Co., Ltd., Osaka (JP)

(72) Inventors: BUNZI MIZUNO, Nara (JP); SHOGO OKITA, Hyogo (JP); MITSURU HIROSHIMA, Osaka (JP); TUTOMU SAKURAI, Nara (JP); NORIYUKI MATSUBARA, Osaka (JP)

(21) Appl. No.: 15/426,341

(22) Filed: Feb. 7, 2017

(30) Foreign Application Priority Data
Mar. 11, 2016 (JP) 2016-048003

(51) Int. Cl. H01L 23/31; H01L 21/56; H01L 21/311; H01L 23/544; H01L 21/268; H01L 21/78

(52) U.S. Cl. CPC H01L 23/3192; H01L 21/268; H01L 21/78; H01L 21/31116; H01L 23/544; H01L 21/56

(57) ABSTRACT

A method of manufacturing an element chip includes an isotropic etching step of removing the first damaged region and the second damaged region through etching the first layer isotropically by exposing the substrate to first plasma after the laser scribing step. The method of manufacturing an element chip further includes a plasma, dicing step of dividing the substrate to a plurality of element chips including the element region through etching the first layer anisotropically by exposing the substrate to second plasma in a state where the second main surface is supported by a supporting member, after the isotropic etching step.

### BACKGROUND

### 1. Technical Field

The present disclosure relates to an element chip and a method for manufacturing the same including a laser scribing step.

### 2. Description of the Related Art

An element chip is manufactured by dicing substrate 30 including first layer 31 that is a semiconductor layer and second layer 32 including an insulating film as illustrated in FIGS. 5A to 5C. Substrate 30 includes dividing region R11 for dividing substrate 30 and a plurality of element regions R12 to be defined by dividing region R11 (FIG. 5A). By removing dividing region R11 of substrate 30, substrate 30 is diced and a plurality of element chips 130 are formed. PTL 1 discloses that substrate 30 is diced through etching with plasma P (FIG. 5C) after scribing dividing region R11 with laser light L (FIG. 5B).

### CITATION LIST

### Patent Literature

PTL 1: Japanese Patent Unexamined Publication (Translation of PCT Application) No. 2013-535114

### SUMMARY

In the laser scribing step (FIG. 5B), generally, damaged region DR is formed on substrate 30 due to thermal influence. Damaged region DR is formed to be wider than dividing region R11 irradiated with laser light by heat propagation. Therefore, damaged region. DR remains on element region R12, that is, an end surface of diced element chip 130, even if dividing region R11 is removed through the plasma etching (FIG. 5C). In a case of crystal disorder or polycrystalline, coarsening of crystal grains is observed in damaged region DR. Therefore, in particular, damaged region DR remaining in first layer 31 tends to be a starting poring for cleavage of first layer 31, and the cleavage may cause element chip 130 to be damaged. That is, in this method, deflective strength of element chip 130 is easily reduced.

An aspect of the present disclosure relates to a method for manufacturing an element chip including a step of preparing a substrate, a laser scribing step, an isotropic etching step after the laser scribing step, and a plasma dicing step to be performed after the isotropic etching step. The step of preparing the substrate is a step of preparing a substrate which has a first main surface and a second main surface and includes a first layer that is a semiconductor layer, a second layer including an insulating film formed on a side of the first main surface of the first layer, a plurality of element regions, and a dividing region for defining the element region. The laser scribing step is a step of forming an opening including an exposing portion where the first layer is exposed at the dividing region by irradiating the dividing region with laser light from the side of the first main surface, forming a first damaged region on a front layer portion of the first layer including the exposing portion, and forming a second damaged region on the front layer portion of the first layer covered with the second layer, that is vicinity of the first damaged region. The isotropic etching step is a step of removing the first damaged region and the second damaged region through etching the first layer isotropically by exposing the substrate to first plasma after the laser scribing step. The plasma dicing step is a step of dividing the substrate to a plurality of element chips including the element region through etching the first layer anisotropically by exposing the substrate to second plasma in a state where the second main surface is supported by a supporting member, after the isotropic etching step.

Another aspect of the present disclosure relates to an element chip including a first layer that is a semiconductor layer having a lamination surface and a surface facing the lamination surface and a second layer including an insulating film which is laminated on the lamination surface, in which the element chip has a recess formed in a peripheral portion of the lamination surface side of the first layer.

### BRIEF DESCRIPTION OF THE DRAWINGS

FIG. 1A is a cross-sectional view illustrating a step of a manufacturing method according to an exemplary embodiment of the present disclosure;

FIG. 1B is a cross-sectional view illustrating a step of a manufacturing method according to the exemplary embodiment of the present disclosure;

FIG. 1C is a cross-sectional view illustrating a step of a manufacturing method according to the exemplary embodiment of the present disclosure;

FIG. 1D is a cross-sectional view illustrating a step of a manufacturing method according to the exemplary embodiment of the present disclosure;

FIG. 2A is a top surface view illustrating a transfer carrier according to the exemplary embodiment of the present disclosure;

FIG. 2B is a cross-sectional view of the transfer carrier according to the exemplary embodiment of the present disclosure taken along line 2B-2B in FIG. 2A;

FIG. 3 is a conceptual diagram illustrating a schematic structure of a plasma processing deice according to the exemplary embodiment of the present disclosure in a cross-section;

FIG. 4 is a cross-sectional view illustrating an element chip according to the exemplary embodiment of the present disclosure;

FIG. 5A is a cross-sectional view illustrating a step of a manufacturing method of an element chip in the related art;

FIG. 5B is a cross-sectional view illustrating a step of the manufacturing method of an element chip in the related art; and.

FIG. 5C is a cross-sectional view illustrating a step of the manufacturing method of an element chip in the related art.

### DETAILED DESCRIPTION

In the present exemplary embodiment, a substrate is diced by a method which does not remain a damaged region due to laser light on a diced element chip. That is, a step of preparing a substrate which has a first main surface and a second main surface and includes a first layer that is a semiconductor layer, a second layer including an insulating film formed on a side of the first main surface of the first layer, a plurality of element regions, and a dividing region for defining each of the element regions is included. A laser scribing step of forming an opening including an exposing portion where the first layer is exposed at the dividing region by irradiating the dividing region with laser light from the side of the first main surface, forming a first damaged region on a front layer portion of the first layer including the exposing portion, and forming a second damaged region on the front layer portion of the first layer covered with the second layer, the second damaged region being in a vicinity of the first damaged region is provided. An isotropic etching step of removing the first damaged region and the second damaged region through etching the first layer isotropically by exposing the substrate to first, plasma after the laser scribing step is provided. A plasma dicing step of dividing the substrate to a plurality of element chips including the element regions through etching the first layer anisotropically by exposing the substrate to second plasma in a state where the second main surface is supported by a supporting member, after the isotropic etching stop is further provided. By these steps, the element chip is manufactured.

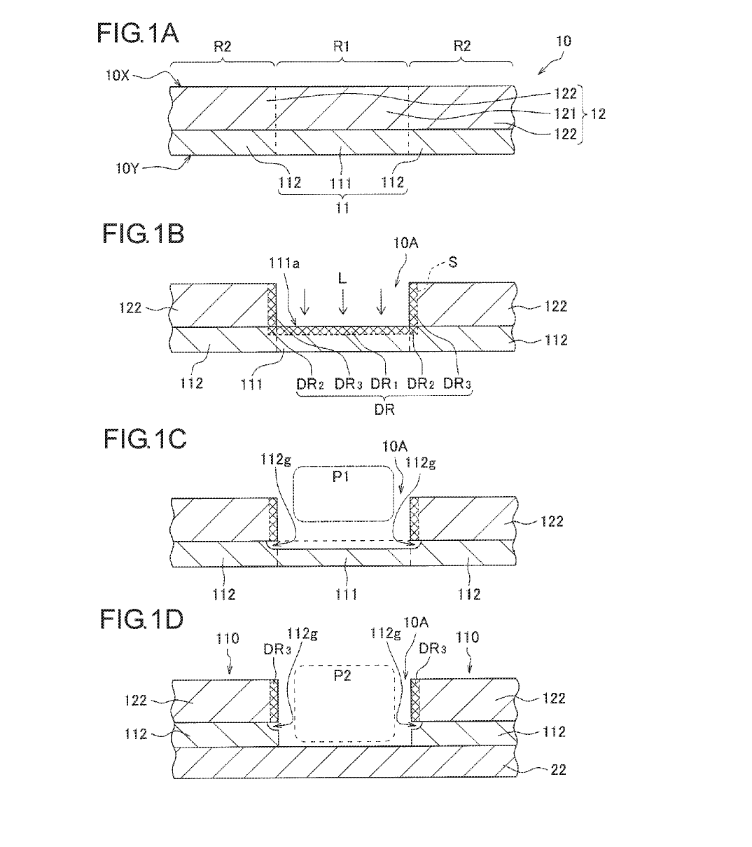

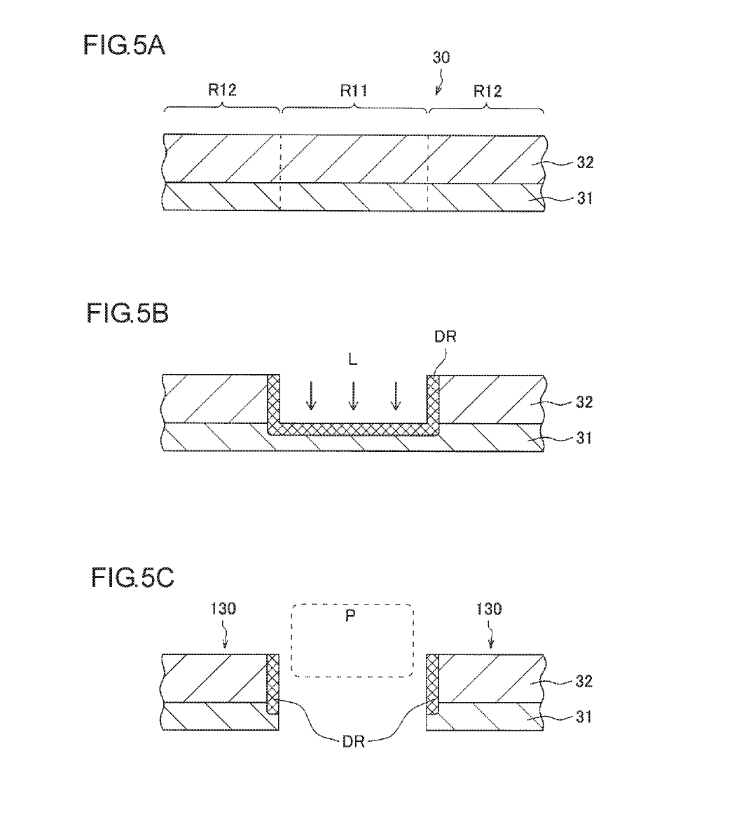

A manufacturing method according to the present exemplary embodiment will be described with reference to FIGS. 1A to 1D. FIGS. 1A to 11) are cross-sectional views illustrating each step of the manufacturing method according to the present exemplary embodiment.

### (1) Preparing Step

Firstly, substrate 10 to be diced is prepared (FIG. 1A). Substrate 10 has first main surface 10X and second main surface 10Y and includes first layer 11 that is a semiconductor layer and second layer 12 including an insulating film which is formed on first main surface 10X side of first layer 11. In addition, substrate 10 is separated into dividing region R1 and the plurality of element regions R2 which are defined by dividing region R1. Accordingly, first layer 11 includes first dividing region 111 corresponding to dividing region R1 and a plurality of first element regions 112 corresponding to element regions R2. Second layer 12 includes a second dividing region 121 corresponding to dividing region R1 and a plurality of second element regions 122 corresponding to element regions R2. A semiconductor circuit, an electric component element, and a circuit layer such as MEMS (which are not illustrated) may be formed on element regions R2 of substrate 10 (first element region 112 and second element region 122).

First layer 11 is a semiconductor layer formed of, for example, silicon (Si), gallium arsenide (GaAs), gallium nitride (GaN), silicon carbide (SiC), or the like. Second layer 12 includes at least an insulating film. For example, the insulating film includes silicon dioxide (SiO₂), silicon nitride (Si₃N₄), lithium tantalate (LiTaO₃), lithium niobate (LiNbO₃), or the like. Second layer 12 may include a multilayer wiring layer (for example, a laminate of a low-k (low dielectric constant) and a copper (Cu) wiring layer), a metal material, a resin protective layer (for example, polyimide), a resist, or the like addition to the insulating film.

### (2) Laser Scribing Step

In the laser scribing step, a part of second dividing region 121 is removed by irradiating second dividing region 121 with laser light L from first main surface 10X side to form opening 10A in which a part of first dividing region 111 is exposed (FIG. 1B). In other words, in the laser scribing step, exposing portion 111a is formed by exposing a part of first dividing region 111. A center wavelength of laser light L is not particularly limited, and is within a range of 350 to 600 nm inclusive, for example.

By the irradiation with laser light L, damaged region DR which is thermally affected by laser light L is formed around opening 10A. Therefore, first damaged region DR1 is formed below exposing portion and second damaged region DR2 is also formed on a front layer portion of first layer 11 covered with second layer 12 that is vicinity of first damaged region DR1. Second damaged region DR2 is formed, for example, so as to sandwich or surround first damaged region DR1. In also the end surface of second element region 122, third damaged region DR3 is formed. In FIGS. 1B to 1D, boundary surface S between damaged region DR and the other regions is indicated by a broken line. The thicknesses of first damaged regions DR1, DR2, and DR3 is changed depending on a radiation condition of laser light L or a material of a portion to be irradiated with laser light L, and are about 0.1 to 10 μm, for example.

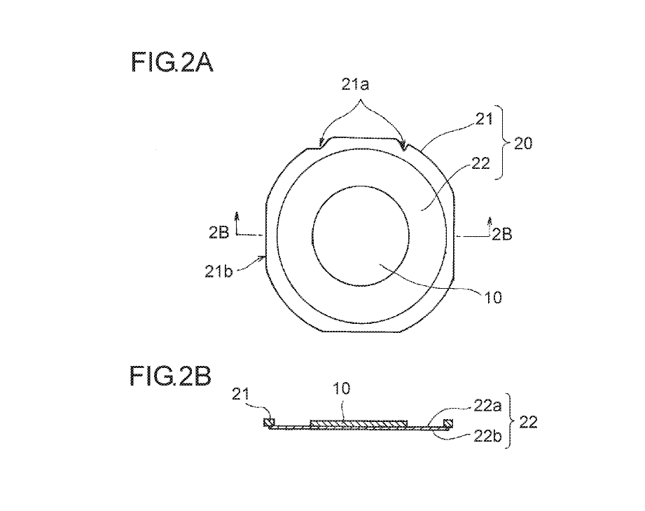

From the viewpoint of handling property, a step after the exposing step using the plasma etching is preferably performed in a state where second main surface 10Y is supported by supporting member 22 (refer to FIG, 1D). The material of supporting member 22 is not particularly limited. Among the materials, when considering that substrate 10 is diced in a state where substrate 10 is supported by supporting member 22, from the viewpoint that element chip 110 to be obtained is easily picked up, supporting member 22 is preferably a flexible resin film. In this case, from the viewpoint of handling property, supporting member 22 is fixed to frame 21. Hereinafter, frame 21 and supporting member 22 which is fixed to frame 21 are collectively referred to as transfer carrier 20. FIG. 2A is a top surface view of transfer carrier 20 and FIG. 2B is a cross-sectional view of transfer carrier 20 taken along line 2B-2B of FIG. 2A.

The material of the resin film is not particularly limited, and examples thereof include a thermoplastic resin such as polyolefins such as polyethylene and polypropylene and polyester such as polyethylene terephthalate. Various additives such as a rubber component (for example, ethylene-propylene rubber (EPM), ethylene-propylene-diene rubber (EPDM), or the like) for applying stretchability, a plasticizer, a softener, an antioxidant, a conductive material, and the like may be blended to the resin film. In addition, the thermoplastic resin may have a functional group that exhibits a photopolymerization reaction such as an acrylic group.

For example, supporting member 22 includes a surface having an adhesive (adhesive surface 22a) and a surface having no adhesive (non-adhesive surface 22b). The outer peripheral edge of adhesive surface 22a is adhered to one surface of frame 21 and covers the opening of frame 21. The substrate 10 is adhered and supported on a portion which is exposed from the opening of frame 21 of adhesive surface 22a. When the plasma process is performed, supporting member 22 is mounted on the stage such that the plasma processing stage (hereinafter, simply referred to as a stage) is in contact with non-adhesive surface 22b.

Adhesive surface 22a is preferably formed of the adhesive component in which the adhesive force is reduced by irradiation with an ultraviolet lay (UV). Accordingly, when element chip 110 is picked up after the plasma dicing, element chip 110 is easily peeled off from adhesive surface 22a by performing UV irradiation, element chip 110 is easily picked up. For example, supporting member 22 is obtained by applying a UV curable acrylic adhesive on one surface of a resin film in a thickness of 5 to 20 μm.

Frame 21 is a frame body having an opening with an area equal to or larger than the entire area of semiconductor substrate 10 and has a predetermined width and a substantially constant thin thickness. Frame 21 has the rigidity to extent that supporting member 22 and semiconductor substrate 10 can be transported in a state where supporting member 22 and semiconductor substrate 10 are held. The shape of the opening of frame 21 is not particularly limited. However, the shape thereof may be a polygon such as a circle, a rectangle, a hexagon, or the like. Notch 21a or corner cut 21b for positioning may be provided in frame 21. Examples of the material of frame 21 include metals such as aluminum and stainless steel, a resin, or the like.

### (3) Isotropic Etching Step

After the laser scribing step, and before the plasma dicing step, opening. 10A is exposed to first plasma P1 (FIG. 1C). In this time, second element region 122 serves as a mask. However, by etching under the etching condition for proceeding the etching isotropically, second damaged region DR2 covered with second layer 12 is etched in addition to first damaged region DR1 exposing from opening 10A. In this case, round-shaped recess 112g is formed below second element, region 122 around opening 10A.

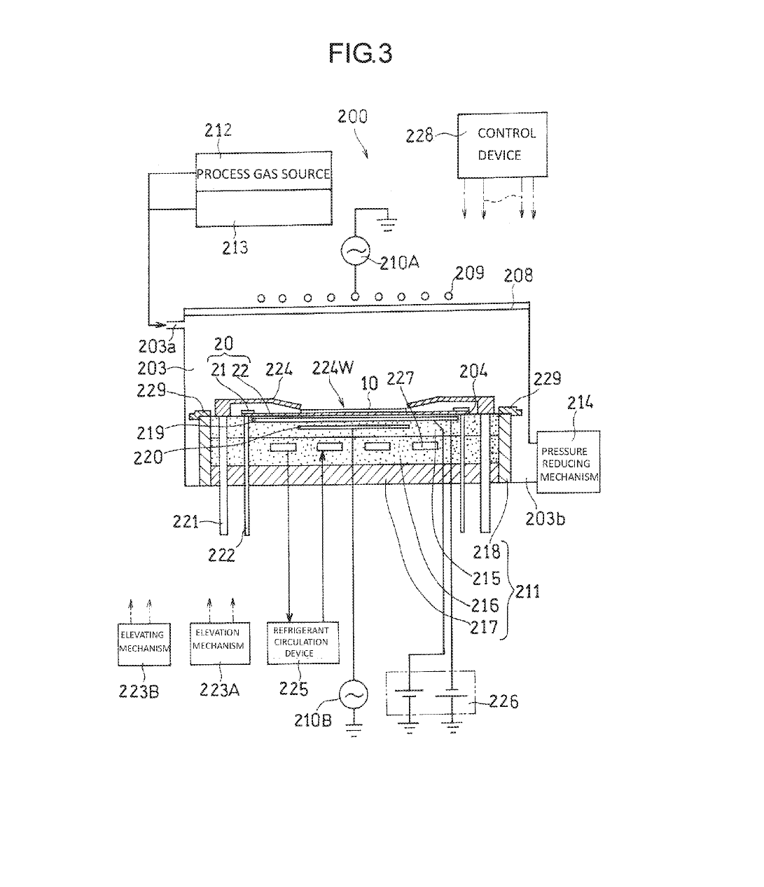

Plasma processing device 200 to be used in the isotropic etching (plasma etching) and the plasma dicing steps will be described in detail with reference to FIG. 3. However, the plasma processing device is not limited thereto. FIG. 3 illustrates a cross section of a structure of plasma processing device 200 to be used in the present exemplary embodiment.

Plasma processing device 200 includes stage 211. Transfer carrier 20 is mounted on stage 211 such that the surface, on which semiconductor substrate 10 of supporting member 22 is held, faces upward. Cover 224 having window portion 224W for covering at least a part of frame 21 and supporting member 22 and for exposing at least a part of substrate 10 is disposed above stage 211.

Stage 211 and cover 224 are disposed inside the reaction chamber (vacuum chamber 203). Vacuum chamber 203 has a roughly cylindrical shape with an upper potion opened and the upper opening is closed by dielectric member 208 that is a lid. As a material configuring vacuum chamber 203, aluminum, stainless steel (SUS), aluminum in which the surface is alumite-processed, and the like can be exemplified. As the material configuring dielectric member 208, a dielectric material such as yttrium oxide (Y₂O₃), aluminum nitride (AlN), alumina (Al₂O₃), quartz (SiO₂), and the like can be exemplified. Antenna 209 as an upper electrode is disposed above dielectric member 208. Antenna 209 is electrically connected to first high frequency power supply 210A. Stage 211 is disposed at the bottom portion side inside vacuum chamber 203.

Gas feed port 203a is connected to vacuum chamber 203. Process gas source 212 and ashing gas source 213 that are a supply source of the process gas is connected to gas feed port 203a respectively, by pipes. In addition, exhaust port 203b is provided on vacuum chamber 203, and pressure reducing mechanism 214 including a vacuum pump for evacuating the gas in vacuum chamber 203 and decompressing the gas is connected to exhaust port 203b.

Stage 211 includes electrode layer 215, metal layer 216, base 217 for supporting, electrode layer 215 and metal layer 216, and outer peripheral portion 218 surrounding electrode layer 215, metal layer 216, and base 217 which have substantially circular shape. Outer peripheral portion 218 is configured of the metal layer with conductivity and etching resistance, and protects electrode layer 215, metal layer 216, and base 217 from the plasma. Annular outer peripheral ring 229 is disposed on the upper surface of outer peripheral portion 218. Outer peripheral ring 229 serves to protect the upper surface of outer peripheral portion 218 from the plasma. Electrode layer 215 and outer peripheral ring 229 are configured of, for example, the above-described dielectric material.

An electrode portion (hereinafter, referred to as an ESC electrode 219) for configuring electrostatic suction mechanism and high frequency electrode portion 220 which is electrically connected to second high frequency power surface 210B are disposed inside electrode layer 215. Direct-current power supply 226 is electrically connected to ESC electrode 219. The electrostatic suction mechanism is configured of ESC electrode 219 and direct-current power supply 226.

Metal layer 216 is configured of, for example, aluminum in which an alumite coating is formed on the surface thereof. Coolant flow path 227 is formed in metal layer 216. Coolant flow path 227 cools stage 211. By cooling stage 211, supporting member 22 mounted on stage 211 is cooled and cover 224 in which a part thereof is in contact with stage 211 is also cooled. Accordingly, substrate 10 or supporting member 22 is suppressed from being damaged by being heated during plasma processing. The coolantin coolant flow path 227 is circulated by refrigerant circulation device 225.

A plurality of supporting portions 222 passing through stage 211 is disposed in the vicinity of stage 211. Supporting portion 222 is driven to move up and down by elevation mechanism 223A. When transfer carrier 20 is transported into vacuum chamber 203, transfer carrier 20 is transferred to supporting portion 222 which is raised to a predetermined position. Supporting portion 222 supports frame 21 of transfer carrier 20. The upper end surface of supporting member 22 descends to the same level as stage 211. Accordingly, transfer carrier 20 is mounted on a predetermined position of stage 211.

A plurality of elevating rods 221 are connected to the end portion of cover 224, thereby capable of elevating cover 224. Elevating rod 221 is driven to move up and down by elevating mechanism 223B. The elevating operation of cover 224 by elevating mechanism 223B can be performed independently of elevation mechanism 223A.

Control device 228 controls an operation of an element for configuring plasma processing device 200 including first high frequency power supply 210A, second high frequency power surface 210B, process gas source 212, aching gas source 213, pressure reducing mechanism 214, refrigerant circulation device 225, elevation mechanism 223A, elevating mechanism 22313, and the electrostatic suction mechanism.

Although the condition of the isotropic etching step is not particularly limited, from the viewpoint of that first dividing region 111 is etched and the etching is easily progressed isotropically, a process gas containing fluorine such as sulfur hexafluoride (SF₆) is preferably used. The isotropic etching step can be performed under the conditions that the pressure in vacuum chamber is adjusted to 5 to 30 Pa, power to be inputted from first high frequency power supply 210A to antenna 209 is set to 1500 to 3600 W, and power to be inputted from second high frequency power surface 210B to high frequency electrode portion 220 is set to 0 to 200 W, while supplying 200 to 400 sccm of SF₆ as a raw material, for example. As the raw material gas, it is preferable to use SF₆ and helium (He) as a diluents gas. In a case where He is used, a flow rate of the row material gas can be set to, for example, SF₆/He=200 to 300 sccm/400 to 600 sccm. By using He as a diluents gas, roughness of the etching surface (front surface of first dividing region 111) at the time of isotropic etching can be suppressed. Furthermore, by using He, it is possible to subject the end surface of second element region 122 to isotropic etching into a tapered shape in descending order of straightness. The scan is a unit of a flow rate and 1 sccm is an amount of the gas in a standard state (0° C., 1 atmosphere) flowing 1 cm³ per a minute.

Here, when an oxide film is present on the front surface of opening 10A, there is a case where the isotropic etching is hindered. Prior to the isotropic etching (main etching) under the etching condition, a preliminary etching (breakthrough) for removing the oxide film that may be present on the front surface of opening 10A may be performed. Preliminary etching can be performed under the condition that a larger power is supplied from second high frequency power surface 210B to high frequency electrode portion 220, as compared with the condition of the main etching.

### (4) Plasma Dicing Step

Next, substrate 10 is exposed to plasma. P2 in a state where second main surface 10Y is supported by supporting member 22 (FIG. ID). Plasma P2 is generated under the condition in which first dividing region 111 is anisotropically etched. For example, a process gas including fluorine such as sulfur hexafluoride (SF₆) is used and a bias voltage is applied by applying high frequency power to high frequency electrode portion 220. Accordingly, the etching is anisotropically performed in a direction parallel to the thickness of substrate 10. The above-described etching condition can be appropriately selected depending on the material of first layer 11. In a case where first layer 11 includes Si, a so-called Bosch process can be used for etching first dividing region 111. In the Bosch process, a stacked film stacking step, a stacked film etching step, and a Si etching step are sequentially repeated to dig first dividing region 111 in the depth direction.

For example, the stacked film stacking step is performed under the conditions that the pressure in vacuum chamber 203 is adjusted to 15 to 25 Pa, power to be inputted from first high frequency power supply 210A to antenna 209 is set to 1500 to 2500 W, power to be inputted from second high frequency power surface 210B to high frequency electrode portion 220 is set to 0 W, and the process is performed for 5 to 15 seconds, while supplying 150 to 250 sccm of C₄F₈ as a raw material.

For example, the stacked film etching step is performed under the conditions that the pressure in vacuum chamber 203 is adjusted to 5 to 15 Pa, power to be inputted from first high frequency power supply 210A to antenna 209 is set to 1500 to 2500 W, power to be inputted from second high frequency power surface 210B to high frequency electrode portion 220 is set to 100 to 300 W, and the process is performed for 2 to 10 seconds, while supplying 200 to 400 sccm of SF₆ as a raw material.

For example, the Si etching step is performed under the conditions that the pressure in vacuum chamber 203 is adjusted to 5 to 15 Pa, power to be inputted from first, high frequency power supply 210A to antenna 209 is set to 1500 to 2500 W, power to be inputted from second high frequency power surface 210B to high frequency electrode portion 220 is set to 50 to 200 W, and the process is performed for 10 to 20 seconds, while supplying 200 to 400 sccm of SF₆ as a raw material.

Under the above conditions, the stacked film stacking step, the stacked film etching step, and the Si etching step are sequentially repeated to subject etching to first dividing region 111 in the depth direction at a rate of 10 μm/min.

In also this case, second element region 122 serves as the mask. Therefore, in the plasma dicing step, from the surface which is exposed by removing first damaged region DR1 in the isotropic etching step, first dividing region 111 which is formed on the surface is etched. Accordingly, substrate 10 is diced to a plurality of element chips 110 including element, regions R2. That is, damaged region DR as the starting point of cleavage does not remain on the end surface of first element region 112 of element chip 110 to be obtained. Therefore, when element chip 110 is used, element chip 110 is suppressed from being damaged, even when external force (bending, impact, or the like) is applied. The etching in the plasma dicing step is the isotropic etching for masking second element region 122 as described above. Therefore, round-shaped recess 112g which is formed under second element region 122 in the isotropic etching step remains even after the plasma dicing step.

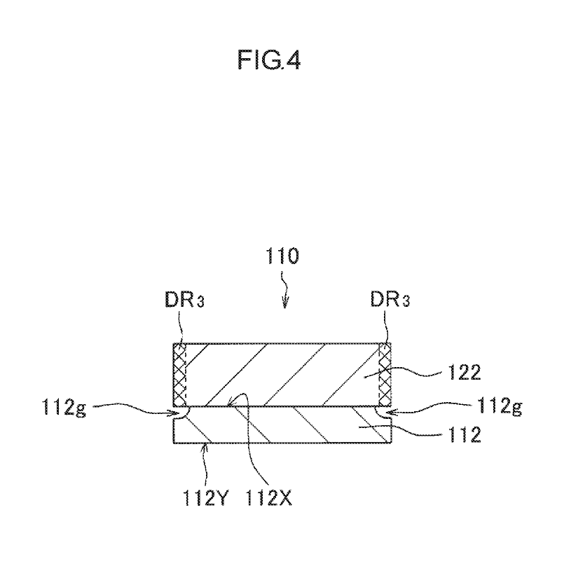

A cross-section of element chip 110 to be obtained in this manner is illustrated in FIG. 4. Element chip 110 includes a first layer (first element region 112) that is a semiconductor layer having lamination surface 112X and surface 112Y which is located at a side facing lamination surface 112X and a second layer (second element region 122) including an insulating film which is laminated on lamination surface 112X. Furthermore, element chip 110 has recess 112g which is formed in a peripheral portion of lamination surface 112X side of the first layer.

In element chip 110, in particular, damaged region DR does not remain on the end surface of first element region 112 in which the readily occur. Therefore, when element chip 110 is used, cracks or clips in element chip 110 can be suppressed, even when external force (bending, impact, or the like) is applied. In addition, in the present exemplary embodiment, substrate 10 is diced in a state where substrate 10 is suppressed by supporting member 22. Therefore, after dicing, element chip 110 to be obtained is picked up while peeling off from supporting member 22. Also in this case, since damaged region DR does not remain on the end surface of first element region 112, element chip 110 is picked up without being damaged.

On the other hand, third damaged region DR3 remains on the end surface of second element region 122. Third damaged region DR3 which is formed by thermal influence of laser light L has a higher reactive than the usual manner and easily absorbs impurities. That is, the impurities (for example, moisture, solder component applied to the front surface of second element region 122, or the like) to be entered from the outside are diffused into third damaged region DR3 and are captured (absorption or suction) in third damaged region DR3. Therefore, the diffusion of the impurities inside element chip 110 can be suppressed. Accordingly, the deterioration of performance of element chip 110 is suppressed.

According to the method according to the present disclosure, since the element chip with excellent deflective strength is obtained, the method is useful as a method for manufacturing the element chip from various substrates.

What is claimed is:

1. A method for manufacturing an element chip, comprising:
a step of preparing a substrate which has a first main surface and a second main surface and includes a first layer that is a semiconductor layer, a second layer including an insulating film formed on a side of the first main surface of the first layer, a plurality of element regions, and a dividing region for defining each of the element regions;
a laser scribing step of forming an opening including an exposing portion where the first layer is exposed at the dividing region by irradiating the dividing region with laser light from the side of the first main surface, forming a first damaged region on a front layer portion of the first layer including the exposing portion, and forming a second damaged region on the front layer portion of the first layer covered with the second layer, the second damaged region being in a vicinity of the first damaged region;
an isotropic etching step of removing the first damaged region and the second damaged region through etching the first layer isotropically by exposing the substrate to first plasma after the laser scribing step; and
a plasma dicing step of dividing the substrate to a plurality of element chips including the element regions through etching the first layer anisotropically by exposing the substrate to second plasma in a state where the second main surface is supported by a supporting member, after the isotropic etching step,

2. The method of claim 1,
wherein in the isotropic etching step, the first plasma is generated by using a process gas containing sulfur hexafluoride as a raw material.

3. An element chip comprising:
a first layer that is a semiconductor layer having a lamination surface and a surface facing the lamination surface; and
a second layer including an insulating film which is laminated on the lamination surface,
wherein the element chip has a recess formed in a peripheral portion of a lamination surface side of the first layer.
